(19) United States
(12) Patent Application Publication
(10) Pub. No.: US 2014/0197889 A1
(43) Pub. Date: Jul. 17, 2014

(54) SEMICONDUCTOR DEVICE, METHOD FOR MANUFACTURING THE SAME, POWER SUPPLY DEVICE, AND HIGH-FREQUENCY AMPLIFIER

(71) Applicant: FUJITSU LIMITED, Kawasaki-shi (JP)

(72) Inventor: Kozo Makiyama, Kawasaki (JP)

(73) Assignee: FUJITSU LIMITED, Kawasaki-shi (JP)

(21) Appl. No.: 14/088,977

(22) Filed: Nov. 25, 2013

(30) Foreign Application Priority Data
Jan. 17, 2013 (JP) 2013-006460

(51) Int. Cl. H01L 29/778; H02M 3/335; H03F 3/16

(52) U.S. Cl. CPC H01L 29/778; H03F 3/16; H02M 3/335
USPC 330/277; 257/194; 438/172; 363/17

(57) ABSTRACT

A semiconductor device includes: a compound semiconductor stack structure including a plurality of compound semiconductor layers stacked over a semiconductor substrate; a first insulating film covering the surface of the compound semiconductor stack structure; and a conductive film provided on the surface of the first insulating film.

### CROSS-REFERENCE TO RELATED APPLICATION

This application is based upon and claims the benefit of priority of the prior Japanese Patent Application No. 2013-006460, filed on Jan. 17, 2013, the entire contents of which are incorporated herein by reference.

### FIELD

The embodiments discussed herein are related to semiconductor devices, methods for manufacturing the same, power supply devices, and high-frequency amplifiers.

### BACKGROUND

High electron mobility transistors (HEMT) having GaN (GaN-HEMT) are an example of semiconductor devices with a compound semiconductor stack structure including compound semiconductors such as nitride semiconductors. For example, high-output devices having GaN-HEMT may be used in power supply devices, and high-frequency devices having GaN-HEMT may be used in high-frequency amplifiers.

High-voltage operation of these devices results in the occurrence of current collapse, which is a phenomenon in which the on resistance is increased to lower drain current (source-drain current). The occurrence of this current collapse decreases output characteristics of the devices such as output and efficiency.

A technique to reduce current collapse is to provide an insulating film covering the surface of a compound semiconductor stack structure.

However, it has been found that when an insulating film is provided to cover the surface of a compound semiconductor stack structure as taught by the above technique, electrons are captured by traps present on the surface of the insulating film during high-voltage operation, thus causing a decrease in drain current.

That is, it has been found that the application of a high drain voltage to the above device in order to enhance output characteristics of the device produces a strong electric field which is applied to the vicinity of the gate electrode, and some of the electrons running through the channel are accelerated by this strong electric field and transit to the surface of the compound semiconductor stack structure, with the result that some of the electrons that have transited are captured by traps present on the surface of the insulating film covering the surface of the compound semiconductor stack structure, thus causing a decrease in drain current.

Thus, it has been found that while the formation of an insulating film covering the surface of a compound semiconductor stack structure as taught by the above technique may reduce current collapse compared to when there is no such an insulating film, sufficient reduction of current collapse is infeasible because traps present on the surface of the insulating film capture electrons and this causes a decrease in drain current.

The following is reference document:
[Document 1] Japanese Laid-open Patent Publication No. 2010-287605.

### SUMMARY

According to an aspect of the invention, a semiconductor device includes: a compound semiconductor stack structure including a plurality of compound semiconductor layers stacked over a semiconductor substrate; a first insulating film covering the surface of the compound semiconductor stack structure; and a conductive film provided on the surface of the first insulating film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic sectional view illustrating a configuration of a semiconductor device according to a first embodiment;

FIG. 2A to FIG. 2L are schematic sectional views illustrating a method for manufacturing semiconductor devices according to the first embodiment;

FIG. 3A is a diagram illustrating IV characteristics of a semiconductor device according to the first embodiment, and FIG. 3B is a diagram illustrating IV characteristics of a semiconductor device without a conductive film;

FIG. 4 is a schematic sectional view illustrating a configuration of a semiconductor device according to a first modification of the first embodiment;

FIG. 5 is a schematic sectional view illustrating a configuration of a semiconductor device according to a second modification of the first embodiment;

FIG. 6 is a schematic sectional view illustrating a configuration of a semiconductor device according to a third modification of the first embodiment;

FIG. 7 is a schematic view illustrating a configuration of a power supply device according to a second embodiment; and

FIG. 8 is a schematic view illustrating a configuration of a high-frequency amplifier according to a third embodiment.

### DESCRIPTION OF EMBODIMENTS

Hereinafter, semiconductor devices, methods for manufacturing the same, power supply devices, and high-frequency amplifiers according to embodiments will be described with reference to the drawings.

### First Embodiment

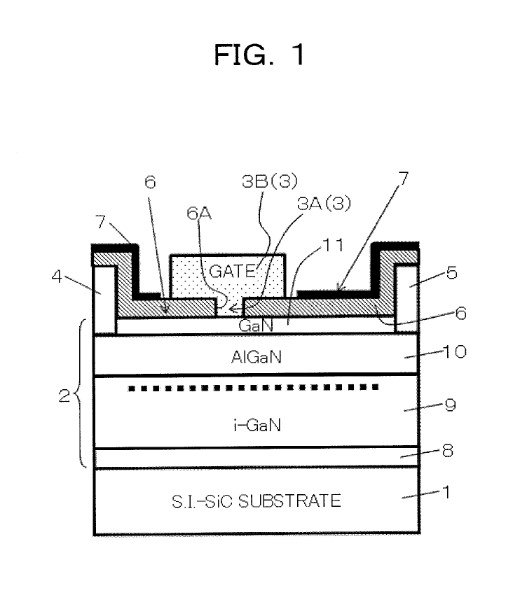

First, semiconductor devices and methods for manufacturing the same according to the first embodiment will be described with reference to FIGS. 1 to 3B.

A semiconductor device in the present embodiment is a compound semiconductor device having compound semiconductors such as nitride semiconductors. Here, a Schottky field effect transistor (FET) having nitride semiconductors, in detail, a Schottky GaN-HEMT will be described as an example which is used in devices such as high-output devices and high-frequency devices and has a nitride semiconductor stack structure (a HEMT structure) with GaN as an electron transfer layer and AlGaN as an electron supply layer.

The semiconductor device includes, as illustrated in, for example, FIG. 1, a compound semiconductor stack structure 2 including a plurality of compound semiconductor layers stacked on a semiconductor substrate 1, a gate electrode 3 in Schottky contact with the compound semiconductor stack structure 2, a pair of ohmic electrodes 4 and 5 in ohmic contact with the compound semiconductor stack structure 2, a first insulating film 6 covering the surface of the compound semiconductor stack structure 2, and a conductive film 7 provided on the surface of the first insulating film 6.

Here, the compound semiconductor stack structure 2 is a nitride semiconductor stack structure in which a buffer layer 8, a GaN electron transfer layer 9, an AlGaN electron supply layer 10 and a GaN surface layer (a cap layer) 11 are sequentially stacked on the semi-insulating SiC substrate 1. In this case, as indicated with a dotted line in FIG. 1, a two-dimensional electron gas (2 DEG) is formed in the vicinity of the interface between the GaN electron transfer layer 9 and the AlGaN electron supply layer 10. Further, the gate electrode 3 is disposed on the GaN surface layer 11, and the pair of ohmic electrodes, namely, a source electrode 4 and a drain electrode 5 are disposed on the AlGaN electron supply layer 10 on both sides with the gate electrode 3 interposed therebetween.

The first insulating film 6 is disposed to cover the surface of the compound semiconductor layer (in the illustrated case, the GaN surface layer 11) in the compound semiconductor stack structure 2 as well as the surface of the source electrode 4 and the surface of the drain electrode 5. But the configuration is not limited to this as long as the first insulating film 6 covers at least the surface of the compound semiconductor stack structure 2. In the illustrated case, the first insulating film 6 is disposed in contact with the surface of the compound semiconductor stack structure 2.

Here, the first insulating film 6 is, for example, a silicon nitride film (a SiN film). The SiN film as the first insulating film 6 is an insulating film having excellent insulating properties, namely, a stoichiometric silicon nitride film having a correct stoichiometric ratio (N/Si=4/3). The refractive index (refractive index to 633 nm wavelength light) of the SiN film as the first insulating film 6 is or is close to 2.0 (namely, in the range greater than 1.9 and lower than 2.1). With this configuration, high insulating properties may be ensured. The first insulating film 6 is not limited to a SiN film. The first insulating film 6 may be a single layer or a multilayer structure.

The conductive film 7 is provided on a region of the surface of the first insulating film 6 excluding the region on which the gate electrode 3 is disposed and a region in the vicinity of that region. Although not illustrated, the conductive film 7 is connected to wires and electrodes which may release electrons therethrough. In the illustrated case, the conductive film 7 is in contact with the surface of the first insulating film 6 in contact with the surface of the compound semiconductor stack structure 2.

Here, the conductive film 7 is a conductive silicon nitride film (a conductive SiN film). That is, the conductive film 7 is a conductive SiN film with conductive properties which includes the same material as the SiN film as the first insulating film 6 disposed underneath thereof. Further, the conductive SiN film as the conductive film 7 is a Si-rich SiN film. The refractive index (refractive index to 633 nm wavelength light) of the Si-rich SiN film is not less than 2.3. In contrast to the stoichiometric SiN film being an insulating film with excellent insulating properties, the Si-rich SiN film is a conductive film which permits the flow of slight current (leakage current). That is, the Si-rich SiN film is more conductive relative to the stoichiometric SiN film. Thus, the Si-rich SiN film will be also referred to as the weakly conductive film. The conductive film 7 is not limited to a conductive SiN film.

In the present embodiment, the first insulating film 6 has a gate opening (a gate electrode formation opening) 6A which extends to the surface of the compound semiconductor stack structure 2 (in the illustrated case, the surface of the GaN surface layer 11). That is, the surface of the compound semiconductor stack structure 2 (the Schottky surface; in the illustrated case, the surface of the GaN surface layer 11) is exposed at the bottom of the gate opening 6A in the first insulating film 6. The gate electrode 3 is an overhang gate electrode disposed so as to overhang the gate opening 6A in the first insulating film 6, and is in Schottky contact with the surface of the compound semiconductor stack structure 2 (in the illustrated case, the surface of the GaN surface layer 11). Further, the gate electrode 3 has a fine gate portion 3A (a first portion) provided in the gate opening 6A, and an over-gate portion 3B (a second portion) provided on the fine gate portion 3A so as to extend toward the source electrode 4 and the drain electrode 5 and to be in contact with the surface of the first insulating film 6. The conductive film 7 is provided on a region of the surface of the first insulating film 6 excluding the region on which the over-gate portion 3B is disposed and a region in the vicinity of that region. In the illustrated case, the conductive film 7 extends from the vicinity of the gate electrode 3 (in the illustrated case, the end of the over-gate portion 3B on the drain electrode 5 side; drain electrode side over-gate end) to the top of the surface of the drain electrode 5, and on the other side extends from the vicinity of the gate electrode 3 (in the illustrated case, the end of the over-gate portion 3B on the source electrode 4 side; source electrode side over-gate end) to the top of the surface of the source electrode 4 so as to be free from contact with the gate electrode 3. Although not illustrated, the conductive film 7 is connected to wires and electrodes which may release (discharge) electrons therethrough. For example, the conductive film 7 may be connected to the drain electrode 5 and the source electrode 4.

In the above manner, current collapse may be reduced by providing the first insulating film 6 to cover the surface of the compound semiconductor stack structure 2. Further, the conductive film 7 provided on the surface of the first insulating film 6 allows electrons captured by traps on the surface of the first insulating film 6 to be released (discharged) therefrom. According to this configuration, it becomes possible to reduce a decrease in drain current due to electrons being captured by traps present on the surface of the first insulating film 6. Consequently, sufficient reduction of current collapse becomes feasible. The occurrence of band modulation may be remedied by providing the conductive film 7 on the surface of the first insulating film 6 to allow for quick release of electrons captured by traps on the surface of the first insulating film 6. Consequently, it becomes possible to reduce current collapse that is a phenomenon in which current is decreased by the expansion of the depletion layer due to electrons being captured by traps present on the surface of the first insulating film 6.

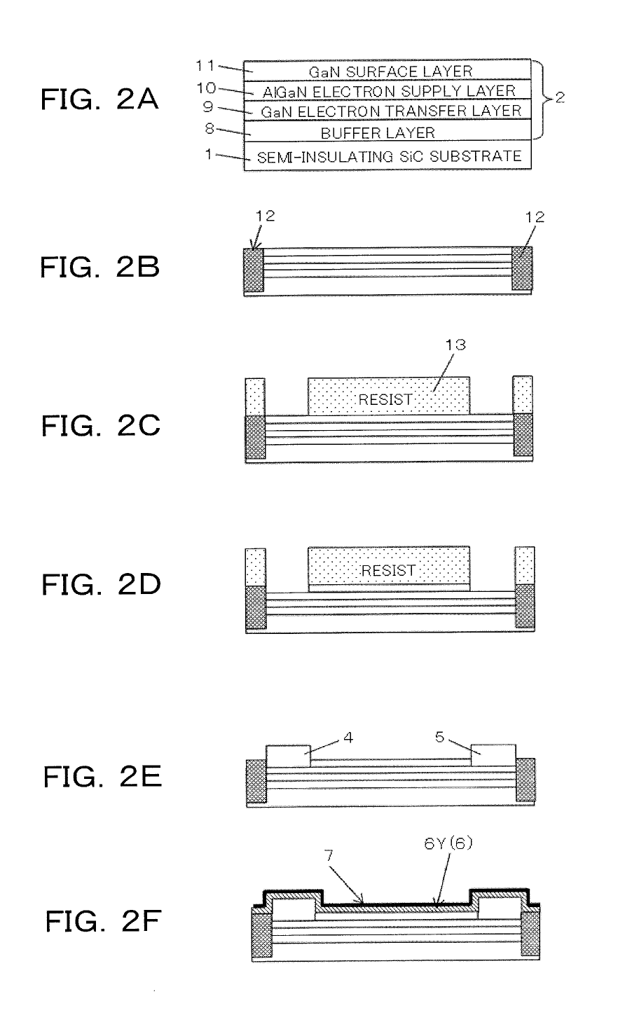

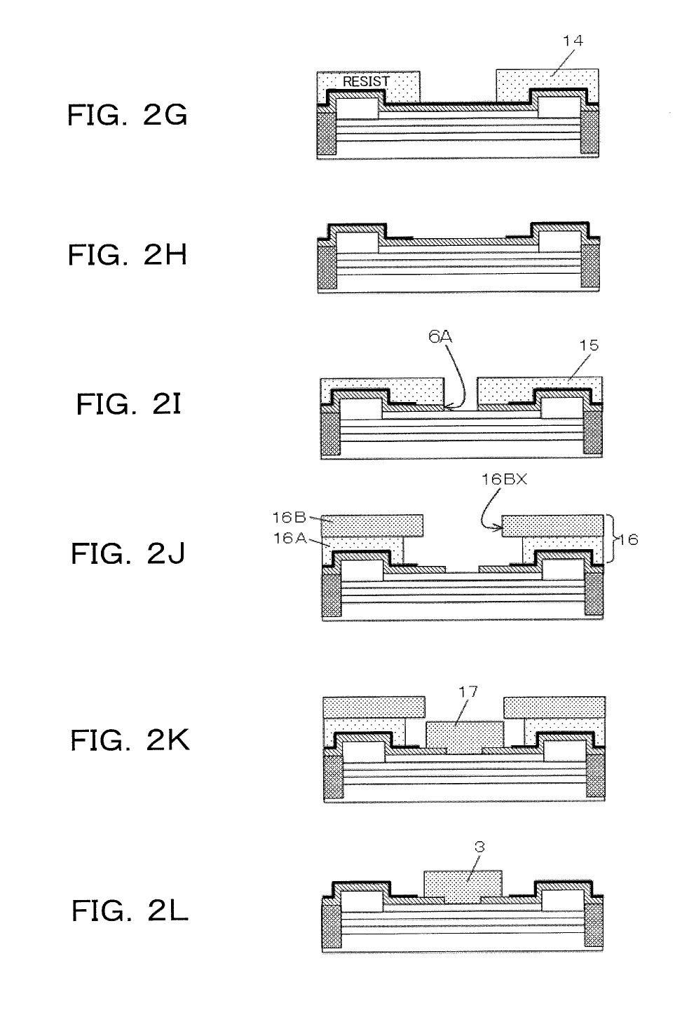

Next, a method for manufacturing the semiconductor devices according to the present embodiment will be described with reference to FIGS. 2A to 2L.

First, as illustrated in FIG. 2A, a buffer layer 8, a GaN electron transfer layer 9, an AlGaN electron supply layer 10 and a GaN surface layer 11 are sequentially epitaxially grown on a semi-insulating SiC substrate 1 (a semiconductor substrate) by, for example, metal organic vapor phase epitaxy (MOVPE), thereby forming a compound semiconductor stack structure 2 which is a stack of a plurality of compound semiconductor layers 8 to 11. The buffer layer 8 has a role of blocking the propagation of lattice defects on the surface of the SiC substrate 1 to the electron transfer layer 9.

Next, as illustrated in FIG. 2B, the entire stack is divided into elements by selective injection of, for example, Ar into the compound semiconductor stack structure 2 as well as a surface portion of the SiC substrate 1. Consequently, element division regions 12 are formed which define active regions.

Next, as illustrated in FIG. 2C, a resist pattern 13 is formed on the compound semiconductor stack structure 2 by, for example, photolithography such that the resist pattern 13 has openings in a source electrode formation region and a drain electrode formation region.

Next, as illustrated in FIG. 2D, the GaN surface layer 11 in the source electrode formation region and the drain electrode formation region is removed by, for example, dry etching with an inert gas and a chlorine-containing gas such as Cl₂ gas while using the resist pattern 13 as a mask. Although the GaN surface layer 11 is illustrated as having been removed throughout the thickness, this etching is not limited thereto. For example, the GaN surface layer 11 may be removed to a depth such that part of the GaN surface layer 11 remains. Alternatively, etching may be effected through the GaN surface layer 11 to a depth in the AlGaN electron supply layer 10.

Next, as illustrated in FIG. 2E, a source electrode 4 and a drain electrode 5 are formed in the respective openings created in the source electrode formation scheduled region and the drain electrode formation scheduled region of the GaN surface layer 11. Here, the source electrode 4 and the drain electrode 5 are formed as a pair of ohmic electrodes on the AlGaN electron supply layer 10 by, for example, sequentially depositing Ti (for example, in a thickness of 20 nm) and Al (for example, in a thickness of 200 nm) by a deposition method, and lifting off, namely, removing the resist pattern 13 having the openings. Thereafter, a heat treatment is carried out at a temperature of, for example, about 550° C. to establish an ohmic contact between the AlGaN electron supply layer 10 and the ohmic electrodes, namely, the source electrode 4 and the drain electrode 5.

Next, as illustrated in FIG. 2F, a silicon nitride film (a SiN film) as a first insulating film 6 is formed so as to cover the entire surface of the compound semiconductor stack structure 2 having the source electrode 4 and the drain electrode 5 as the ohmic electrodes.

In detail, a silicon nitride film as the first insulating film 6 is formed by, for example, plasma chemical vapor deposition (PCVD) on the surface of the compound semiconductor stack structure 2 having the source electrode 4 and the drain electrode 5 as the ohmic electrodes. That is, a silicon nitride film is formed as the first insulating film 6 to cover the surface of the compound semiconductor stack structure 2.

Here, a stoichiometric silicon nitride film having excellent insulating properties is formed as the first insulating film 6. For this purpose, for example, silane and nitrogen as materials are deposited under film production conditions in which the gas flow rates are SiH₄/N₂=about 2.5 sccm/about 500 sccm, the pressure is about 1000 mTorr, the film production temperature is about 300° C. and the RF power is about 50 W, thereby forming a silicon nitride film in a thickness of, for example, 50 nm. The refractive index (refractive index to 633 nm wavelength light) of thus-formed silicon nitride films was found to be close to 2.0. The refractive index was measured using ellipsometry. Because the refractive index of the silicon nitride films is or is close to 2.0 (namely, in the range greater than 1.9 and lower than 2.1), the silicon nitride films are substantially stoichiometrically correct, namely, the N/Si ratio is 4/3. That is, objective stoichiometric silicon nitride films having excellent insulating properties were formed.

Next, as illustrated in FIG. 2F, a conductive film 7 is formed on the first insulating film 6 by, for example, plasma chemical vapor deposition (PCVD). That is, the conductive film 7 is formed on the surface of the first insulating film 6.

Here, a conductive silicon nitride film (a conductive SiN film; a weakly conductive film) is formed as the conductive film 7. For this purpose, for example, silane and nitrogen as materials are deposited under film production conditions in which the gas flow rates are SiH₄/N₂=about 3.0 sccm/about 500 sccm, the pressure is about 1000 mTorr, the film production temperature is about 300° C. and the RF power is about 50 W, thereby forming a conductive silicon nitride film in a thickness of, for example, 2 nm. The refractive index (refractive index to 633 nm wavelength light) of thus-formed conductive silicon nitride films was found to be close to 2.3. The refractive index was measured using ellipsometry. Further, these conductive silicon nitride films are Si-rich silicon nitride films having a refractive index of not less than 2.3 and also exhibiting weak conductive properties. That is, objective conductive silicon nitride films were formed.

In the present embodiment, as discussed above, the first insulating film 6 is formed while supplying SiH₄ as a Si material gas to form a stoichiometric silicon nitride film, and the conductive film 7 is formed while increasing the flow rate of SiH₄ as the Si material gas to form a Si-rich conductive silicon nitride film having a higher refractive index and a lower N/Si ratio. In this case, the conductive film 7 may be formed easily.

Next, as illustrated in FIG. 2G, a resist pattern 14 is formed to have an opening which includes an over-gate portion (of the overhang gate electrode 3) formation scheduled region and which is larger (for example, by about 0.2 μm) than this formation scheduled region. For example, a resist (PFI-32 manufactured by Sumitomo Chemical Co., Ltd.) is applied onto the entire surface; then UV rays are applied to photoexpose a region which includes an over-gate portion (of the overhang gate electrode 3) formation scheduled region and which is larger than this formation scheduled region by about 0.2 μm; and the latent pattern is developed with a developing solution (developing solution NMD-W manufactured by TOKYO OHKA KOGYO CO., LTD.) to form a resist pattern 14 having an opening which includes the over-gate portion (of the overhang gate electrode 3) formation scheduled region and which is larger than this formation scheduled region by about 0.2 μm.

Next, as illustrated in FIG. 2H, the conductive film 7 is treated by, for example, dry etching with SF₆ as the etching gas while using the resist pattern 14 as a mask to remove the conductive film 7 in the region which includes the over-gate portion (of the overhang gate electrode 3) formation scheduled region and which is larger than this formation scheduled region by about 0.2 μm. Thereafter, the resist pattern 14 is removed with a release liquid.

Next, as illustrated in FIG. 21, a gate opening formation resist pattern 15 is formed. For example, a resist (PFI-32 manufactured by Sumitomo Chemical Co., Ltd.) is applied onto the entire surface; then UV rays are applied to photoexpose a gate opening formation region (for example, about 600 nm in length); and the latent pattern is developed with a developing solution (developing solution NMD-W manufactured by TOKYO OHKA KOGYO CO., LTD.) to form a gate opening formation resist pattern 15 having an opening in the gate opening formation region. The gate opening will be also referred to as the fine gate opening or the Schottky gate electrode formation opening.

While using the gate opening formation resist pattern 15 as a mask, the silicon nitride film as the first insulating film 6 is dry etched with, for example, SF₆ as the etching gas to form a gate opening 6A with a length of, for example, about 600 nm (opening width: about 600 nm). Thereafter, the gate opening formation resist pattern 15 is removed with a release liquid.

Next, as illustrated in FIG. 2J, a multilayer resist 16 (in the illustrated case, a two-layered resist) is formed which is composed of a lower resist layer 16A (PMGI manufactured by MicroChem Corp. (USA)) and an upper resist layer 16B (PF132-A8 manufactured by Sumitomo Chemical Co., Ltd.); and the resist is irradiated with radiations such as UV rays and is developed with a developing solution (developing solution NMD-W manufactured by TOKYO OHKA KOGYO CO., LTD.) to form an opening 16BX having a length of, for example, 1.5 μm (opening width: 1.5 μm) in the upper resist layer 16B. The lower resist layer 16A is side-etched during the development of the upper resist layer 16B, and a multilayer resist 16 with a canopy shape is formed.

Next, as illustrated in FIG. 2K, gate metals 17 (Ni: in a thickness of, for example, about 10 nm/Au: in a thickness of, for example, about 300 nm) are deposited onto the entire surface while using the canopy-shaped multilayer resist 16 as a mask. For convenience of illustration, the gate metals 17 deposited on the upper resist layer 16B are not illustrated.

Next, the multilayer resist 16 and the undesired gate metals 17 are removed by lift-off with a hot organic solvent. Thus, as illustrated in FIG. 2L, a gate electrode 3 is formed on the GaN surface layer 11.

Thereafter, although not illustrated, steps are performed to form components such as interlayer insulating films, contact holes and various wires, thus completing the semiconductor devices.

As discussed above, the semiconductor devices and the method for manufacturing the same according to the present embodiment are advantageous in that current collapse may be sufficiently reduced by reducing a decrease in drain current due to electrons being captured by traps present on the surface of the first insulating film 6. That is, semiconductor devices having good current collapse characteristics may be advantageously realized.

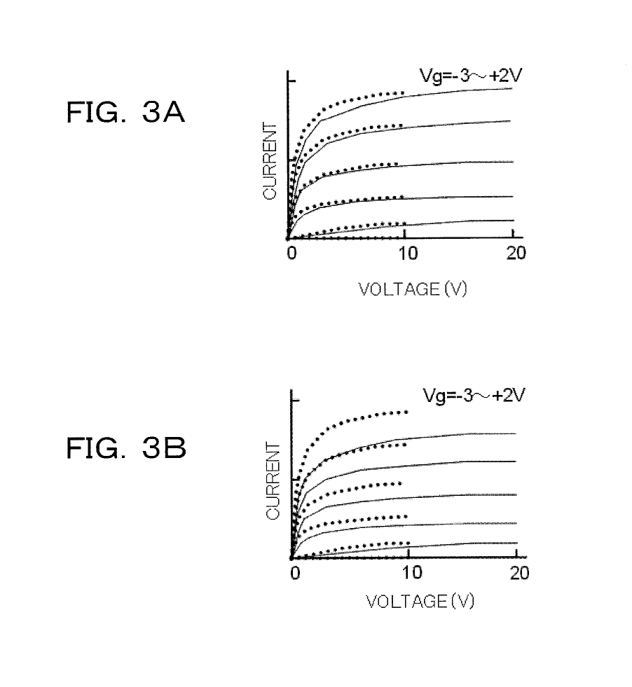

When semiconductor devices having the above structure were actually manufactured by the aforementioned manufacturing method, electrons trapped on the surface of the first insulating film 6 were quickly released via the conductive film 7 and the current collapse phenomenon was markedly reduced compared to semiconductor devices which did not have the conductive film 7. That is, the current collapse phenomenon occurred in semiconductor devices which did not have the conductive film 7, as indicated by pulse IV characteristics illustrated in FIG. 3B. In contrast, the semiconductor devices which included the conductive film 7 as described above exhibited a marked reduction in the current collapse phenomenon as indicated by pulse IV characteristics illustrated in FIG. 3A. In FIGS. 3A and 3B, the dotted lines indicate current-voltage characteristics (drain current-drain voltage characteristics) during low voltage application, and the actual lines indicate current-voltage characteristics (drain current-drain voltage characteristics) during high voltage application.

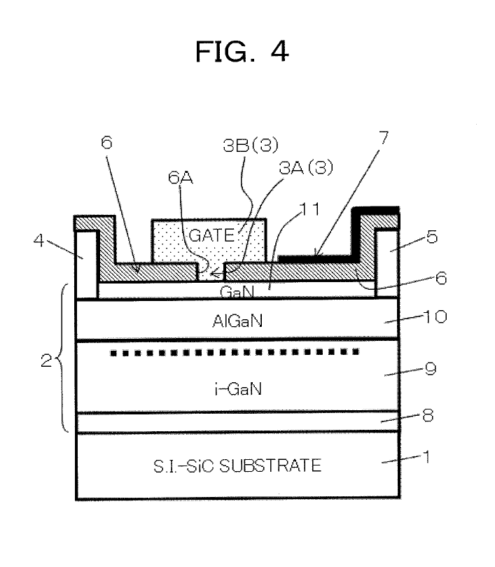

While the conductive film 7 in the above embodiment has been illustrated as being provided on both sides, namely, on the drain electrode 5 side and the source electrode 4 side with respect to the gate electrode 3, the configuration is not limited thereto and may be such that, for example, the conductive film 7 is provided only on the drain electrode 5 side with respect to the gate electrode 3 as illustrated in FIG. 4. That is, the conductive film 7 may be provided to extend only from the vicinity of the gate electrode 3 (in the illustrated case, the drain electrode side over-gate end) to the top of the surface of the drain electrode 5. Such a configuration fulfills the purpose because a strong electric field is applied between the gate electrode end and the drain electrode end, and electrons are more likely to become trapped at the surface of the first insulating film 6 on the drain electrode 5 side with respect to the gate electrode 3. This configuration will be referred to as the first modification. Alternatively, for example, the conductive film 7 may not extend to the top of the surfaces of the drain electrode 5 and the source electrode 4 to cover the drain electrode 5 and the source electrode 4. For example, the conductive film 7 may be provided only between the gate electrode 3 and the drain electrode 5 and between the gate electrode 3 and the source electrode 4. That is, the conductive film 7 may be provided to extend from the vicinity of the gate electrode 3 to the vicinities of the drain electrode 5 and the source electrode 4. Still alternatively, for example, the conductive film 7 may be provided only between the gate electrode 3 and the drain electrode 5. That is, the conductive film 7 may be provided to extend only from the vicinity of the gate electrode 3 to the vicinity of the drain electrode 5.

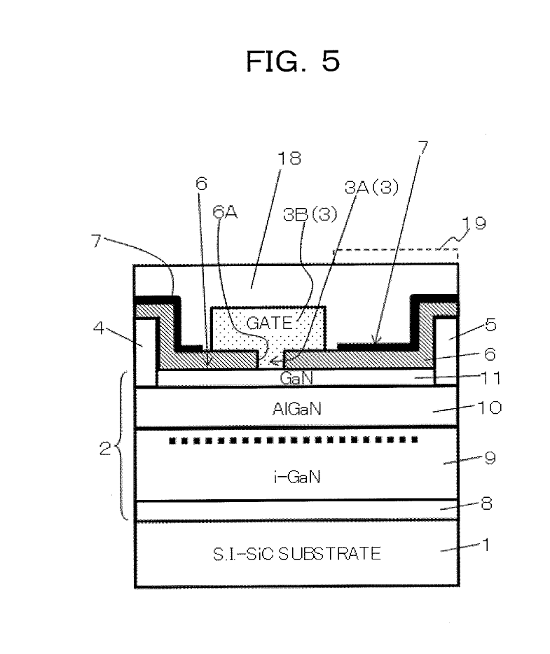

In the aforementioned embodiment, a second insulating film 18 may be further provided to cover the first insulating film 6 and the conductive film 7, for example, as illustrated in FIG. 5. This configuration will be referred to as the second modification. For example, the second insulating film 18 such as a SiN film may be provided to cover the entire surface, namely, the first insulating film 6, the conductive film 7 and the gate electrode 3. In this manner, the reliability of properties such as moisture resistance may be improved. In this case, as indicated with a dotted line in FIG. 5, a conductive film 19 may be provided on the surface of the second insulating film 18. While this configuration has been illustrated as a modification of the aforementioned embodiment, the configuration may be applied also as a modification of the first modification. That is, the second insulating film 18 covering the first insulating film 6 and the conductive film 7 may be provided in the semiconductor devices in which the conductive film 7 is provided only on the drain electrode 5 side with respect to the gate electrode 3 (see FIG. 4).

In the aforementioned embodiment, a field plate may be provided such that at least part of the field plate is located between the gate electrode 3 and the drain electrode 5. For example, a second insulating film 18 covering the first insulating film 6 and the conductive film 7 may be provided, and a source field plate having the same potential as the source may be provided on the second insulating film 18 such that an end of the source field plate is located above between the gate electrode 3 and the drain electrode 5.

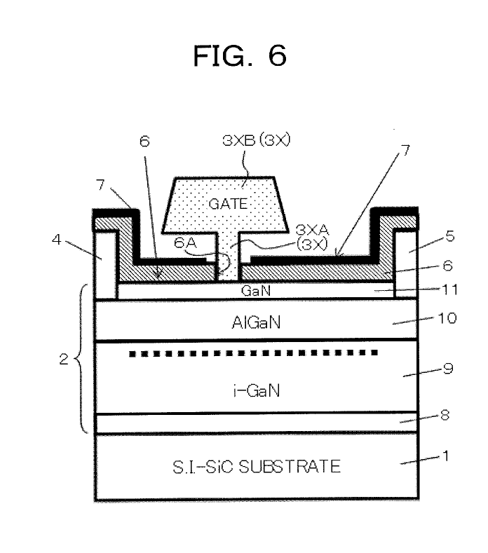

While the overhang gate electrode 3 is used in the aforementioned embodiment, the gate electrode 3 is not limited thereto and may be a T-shaped gate electrode 3X, for example, as illustrated in FIG. 6. In such a case, semiconductor devices exhibiting excellent properties such as high-frequency characteristics may be realized. Such a configuration will be referred to as the third modification. This T-shaped gate electrode 3X has a fine gate portion 3XA (a first portion) provided in the gate opening 6A and extending upward beyond the first insulating film 6, and an over-gate portion 3XB (a second portion) extending over the fine gate portion 3XA toward the source electrode 4 and the drain electrode 5 and provided without contact with the surface of the first insulating film 6. In this case, the conductive film 7 may be appropriately provided in a region on the surface of the first insulating film 6 which includes a region found under the over-gate portion 3XB. That is, the conductive film 7 may be appropriately provided so as to extend from the vicinity of the fine gate portion 3XA of the T-shaped gate electrode 3X to the drain electrode 5 side and to the source electrode 4 side. For example, the conductive film 7 may extend to a position which is approximately 0.1 μm away from the fine gate portion 3XA. Semiconductor devices having such a T-shaped gate electrode 3X have a space between the over-gate portion 3XB of the T-shaped gate electrode 3X, and the conductive film 7 and the first insulating film 6. While this configuration has been illustrated as a modification of the aforementioned embodiment, the configuration may be applied also as a modification of the first modification. That is, the T-shaped gate electrode 3X may be used in the semiconductor devices in which the conductive film 7 is provided only on the drain electrode 5 side with respect to the gate electrode 3 (see FIG. 4). Further, the above configuration may be applied as a modification of the second modification. That is, the T-shaped gate electrode 3X may be used in the semiconductor devices in which the second insulating film 18 is provided to cover the first insulating film 6 and the conductive film 7 (see FIG. 5).

The structure in the aforementioned embodiment is a Schottky structure in which the gate electrode 3 is in Schottky contact with the surface of the compound semiconductor stack structure 2 (in the illustrated case, the surface of the GaN surface layer 11). However, the structure is not limited thereto and may be, for example, a metal-insulator-semiconductor (MIS) structure in which the entire surface of the compound semiconductor stack structure 2 is covered with an insulating film such as a SlN film, an Al₂O₃ film, an AlN film or a HfO₂ film, and the gate electrode 3 is provided on the insulating film. While this configuration has been illustrated as a modification of the aforementioned embodiment, the configuration may be applied also as a modification of any of the first modification to the third modification. That is, an MIS structure may be adopted in these modifications.

While the semiconductor substrate 1 in the aforementioned embodiment is a SiC substrate as an example, the semiconductor substrate 1 is not limited thereto and may be any of other substrates, for example, semiconductor substrates such as sapphire substrates, Si substrates and GaN substrates. Further, the substrates are not limited to semi-insulating substrates and may be, for example, n-type conductive substrates or p-type conductive substrates.

Further, the layer structures of the source electrode 4, the drain electrode 5 and the gate electrode 3 in the aforementioned embodiment are examples and not restrictive. Other layer structures are also usable. For example, the source electrode 4, the drain electrode 5 and the gate electrode 3 in the aforementioned embodiment may have single-layer structures or multilayer structures. Furthermore, the methods for the formation of the source electrode 4, the drain electrode 5 and the gate electrode 3 in the aforementioned embodiment are only examples, and these layers may be formed by any other methods.

The compound semiconductor stack structure 2 constituting GaN-HEMT in the aforementioned embodiment is not limited to the one described above, and may be any structure as long as the structure includes at least a GaN electron transfer layer and an AlGaN electron supply layer. For example, the surface layer may be a layer composed of another material or may be a multilayer structure. Further, for example, the compound semiconductor stack structure 2 may be free of a surface layer. Furthermore, the electron supply layer is not limited to AlGaN, and may be any electron supply layer including any of AlGaN, InAlN and AlInGaN.

While the compound semiconductor stack structure 2 constituting the semiconductor device in the aforementioned embodiment is composed of GaN compound semiconductor materials, the materials are not limited thereto. For example, the compound semiconductor stack structure 2 may be composed of InP compound semiconductor materials. In this case, for example, the compound semiconductor stack structure 2 may be a structure in which a buffer layer, an InGaAs electron transfer layer, an InAlAs electron supply layer, an InP etching stopper layer and an InGaAs low-resistivity layer are sequentially stacked on a semi-insulating InP substrate. As in this case, the compound semiconductor stack structure 2 is not limited as long as the structure includes at least an electron transfer layer and an electron supply layer. For example, any compound semiconductor stack structures may be used which may constitute field effect transistors such as compound semiconductor field effect transistors.

In the aforementioned embodiment, a gate recess may be provided in the compound semiconductor stack structure 2 and the gate electrode 3 may be provided in this gate recess.

### Second Embodiment

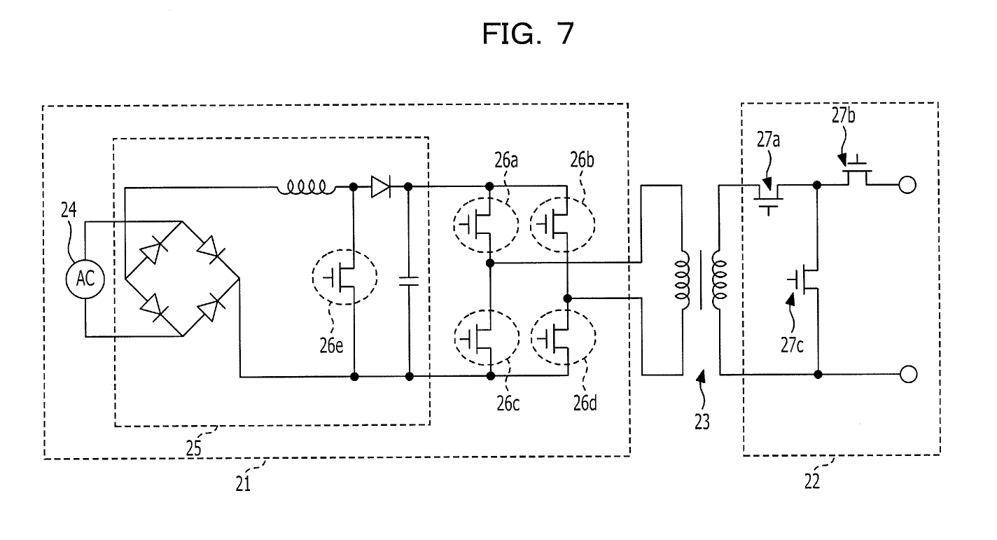

Next, power supply devices according to the second embodiment will be described with reference to FIG. 7.

The power supply device in the present embodiment includes any of the semiconductor devices (HEMT) according to the first embodiment and the modifications described above.

As illustrated in FIG. 7, the power supply device includes a high-voltage primary circuit (a high-voltage circuit) 21, a low-voltage secondary circuit (a low-voltage circuit) 22, and a transformer 23 disposed between the primary circuit 21 and the secondary circuit 22.

The primary circuit 21 includes an alternating-current power supply 24, a so-called bridge rectifier circuit 25, and a plurality (four in the illustrated case) of switching elements 26a, 26b, 26c and 26d. Further, the bridge rectifier circuit 25 has a switching element 26e. The secondary circuit 22 includes a plurality (three in the illustrated case) of switching elements 27a, 27b and 27c.

In the present embodiment, the switching elements 26a, 26b, 26c, 26d and 26e of the primary circuit 21 are the semiconductor devices (HEMT) according to any of the first embodiment and the modifications described above. On the other hand, the switching elements 27a, 27b and 27c of the secondary circuit 22 are usual MIS-FET having silicon.

In the power supply devices of the present embodiment, the semiconductor devices (HEMT) according to any of the first embodiment and the modifications described above are applied to the high-voltage circuit 21. Thus, the power supply devices advantageously realize high reliability.

### Third Embodiment

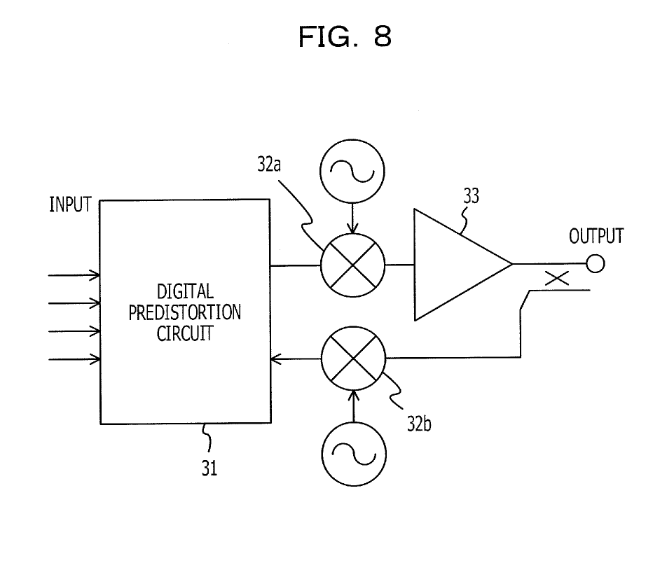

Next, high-frequency amplifiers according to the third embodiment will be described with reference to FIG. 8.

The high-frequency amplifier in the present embodiment includes any of the semiconductor devices (HEMT) according to the first embodiment and the modifications described above.

As illustrated in FIG. 8, the high-frequency amplifier includes a digital predistortion circuit 31, mixers 32a and 32b, and a power amplifier 33. The power amplifier may be simply referred to as the amplifier. The digital predistortion circuit 31 compensates for nonlinear distortion of an input signal. The mixers 32a and 32b perform mixing of an alternating current signal and the input signal whose nonlinear distortion has been compensated for. The power amplifier 33 amplifies the input signal mixed with the alternating current signal and includes any of the semiconductor devices (HEMT) according to the first embodiment and the modifications described above.

In FIG. 8, the high-frequency amplifier is configured such that a signal on the output side may be mixed with an alternating current signal at the mixer 32b and may be transmitted to the digital predistortion circuit 31 by, for example, switching of the switches.

In the high-frequency amplifiers of the present embodiment, the semiconductor devices (HEMT) according to any of the first embodiment and the modifications described above are applied to the power amplifier 33. Thus, the high-frequency amplifiers advantageously realize high reliability.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a compound semiconductor stack structure including a plurality of compound semiconductor layers stacked over a semiconductor substrate;
a first insulating film covering the surface of the compound semiconductor stack structure; and
a conductive film provided on the surface of the first insulating film.

2. The semiconductor device according to claim 1, wherein
the first insulating film is a silicon nitride film; and
the conductive film is a conductive silicon nitride film.

3. The semiconductor device according to claim 1, wherein
the first insulating film is a stoichiometric silicon nitride film having a refractive index to 633 nm wavelength light of or close to 2.0; and
the conductive film is a conductive silicon nitride film having a refractive index to 633 nm wavelength light of not less than 2.3.

4. The semiconductor device according to claim 1, further comprising:
a second insulating film covering the first insulating film and the conductive film.

5. The semiconductor device according to claim 1, further comprising:
a gate electrode provided over the compound semiconductor stack structure; and
a source electrode and a drain electrode provided on both sides with the gate electrode interposed therebetween, wherein
the conductive film is provided on the drain electrode side with respect to the gate electrode.

6. The semiconductor device according to claim 1, further comprising:
a gate electrode provided over the compound semiconductor stack structure; and
a source electrode and a drain electrode provided on both sides with the gate electrode interposed therebetween, wherein
the conductive film is provided on both the drain electrode side and the source electrode side with respect to the gate electrode.

7. The semiconductor device according to claim 1, further comprising:
a gate electrode provided over the compound semiconductor stack structure; and
a source electrode and a drain electrode provided on both sides with the gate electrode interposed therebetween, wherein
the first insulating film has a gate electrode formation opening, the gate electrode has a first portion provided in the gate electrode formation opening, and a second portion provided on the first portion so as to extend toward the source electrode and the drain electrode and to be in contact with the surface of the first insulating film; and wherein
the conductive film is provided on a region of the surface of the first insulating film excluding the region on which the second portion is disposed and a region in the vicinity of the region on which the second portion is disposed.

8. The semiconductor device according to claim 1, further comprising:
a gate electrode provided over the compound semiconductor stack structure; and
a source electrode and a drain electrode provided on both sides with the gate electrode interposed therebetween, wherein
the first insulating film has a gate electrode formation opening, the gate electrode has a first portion provided in the gate electrode formation opening and extending upward beyond the first insulating film, and a second portion extending over the first portion toward the source electrode and the drain electrode and provided without contact with the surface of the first insulating film, and wherein
the conductive film is provided on a region of the surface of the first insulating film including a region found under the second portion.

9. A method for manufacturing semiconductor devices, comprising:
forming a compound semiconductor stack structure by stacking a plurality of compound semiconductor layers over a semiconductor substrate;
forming a first insulating film to cover the surface of the compound semiconductor stack structure; and
forming a conductive film on the surface of the first insulating film.

10. The method for manufacturing semiconductor devices according to claim 9, wherein
the forming of the first insulating film comprises forming a silicon nitride film while supplying SiH₄ as a Si material gas; and
the forming of the conductive film comprises forming a conductive silicon nitride film while increasing the flow rate of SiH₄ compared to the flow rate during the formation of the first insulating film.

11. The method for manufacturing semiconductor devices according to claim 9, further comprising:
forming a second insulating film to cover the first insulating film and the conductive film.

12. A power supply device comprising:
a transformer; and
a high-voltage circuit and a low-voltage circuit disposed with the transformer interposed therebetween, the high-voltage circuit comprising a transistor, the transistor including:
a compound semiconductor stack structure including a plurality of compound semiconductor layers stacked over a semiconductor substrate,
a first insulating film covering the surface of the compound semiconductor stack structure, and
a conductive film provided on the surface of the first insulating film.

13. A high-frequency amplifier comprising:
an amplifier configured to amplify an input signal, the amplifier comprising a transistor, the transistor including:
a compound semiconductor stack structure including a plurality of compound semiconductor layers stacked over a semiconductor substrate,
a first insulating film covering the surface of the compound semiconductor stack structure, and
a conductive film provided on the surface of the first insulating film.
